(19) United States
(12) Patent Application Publication
(10) Pub. No.: US 2026/0114049 A1
(43) Pub. Date: Apr. 23, 2026

(54) SEMICONDUCTOR STRUCTURES AND METHODS OF MANUFACTURING THE SAME

(71) Applicant: Vanguard International Semiconductor Corporation, Hsinchu (TW)

(72) Inventors: Wan-Ting SU, Hsinchu City (TW); Kai-Chuan KAN, Hsinchu City (TW); Chih-Cherng LIAO, Jhudong Township (TW)

(73) Assignee: Vanguard International Semiconductor Corporation, Hsinchu (TW)

(21) Appl. No.: 18/918,863

(22) Filed: Oct. 17, 2024

(51) Int. Cl. H01L 27/12; H01L 21/762; H01L 29/78

(52) U.S. Cl. CPC H10D 87/00; H10P 90/1906; H10P 90/1916; H10W 10/014; H10W 10/061; H10W 10/17; H10W 10/181; H10D 30/66

(57) ABSTRACT

A semiconductor structure includes a substrate, an isolation layer over the substrate, an epitaxial layer over the substrate and covering the isolation layer, and a deep trench isolation that extends into the epitaxial layer. The deep trench isolation connects the isolation layer. The isolation layer is disposed in the second region of the semiconductor structure, but does not extend into the first region of the semiconductor structure. The semiconductor structure further includes a first element formed in the first region and a second element formed in the second region. In addition, the substrate acts as the drain region of the first element. The second element is disposed in an isolation region that is defined by the deep trench isolation and the isolation layer.

### BACKGROUND OF THE INVENTION

### Field of the Invention

The present invention relates to semiconductor structures and methods of manufacturing the same, in particular to semiconductor structures integrating different types of semiconductor elements on the same substrate and methods of manufacturing the same.

### Description of the Related Art

The semiconductor industry continues to improve the integration density of different electronic elements by continuing to reduce the minimum element size, allowing more elements to be integrated in a given region. At the same time, attempts are also made to integrate different types of semiconductor elements on the same substrate. However, as the requirements for the electrical performance of semiconductor elements continue to increase, the complexity of integrating semiconductor elements also increases.

Take laterally diffused metal oxide semiconductor (LDMOS) elements as an example, which meet the requirements of high output power and gate-source breakdown voltage greater than 60 volts. Laterally diffused metal oxide semiconductor (LDMOS) elements are mainly used in high-end audio amplifiers and radio power amplifiers for wireless cellular networks. The driving current of the LDMOS element is in the plane direction. Vertical elements such as vertical diffusion metal oxide semiconductor (VDMOS) elements have the characteristics of high voltage resistance and are widely used in power switch elements. The driving current of VDMOS elements flows in the vertical direction. Currently, the integration of LDMOS elements and VDMOS elements with different driving current directions on the substrate not only increases the complexity of the formation method but also makes the electrical performance of each element in operation easily affected by other different types of elements, making it unable to meet application requirements. Thus, while existing semiconductor elements are, individually, often suitable and sufficient for their intended purposes, they are not entirely satisfactory for integrated fabrication.

### BRIEF SUMMARY OF THE INVENTION

Some embodiments of the present disclosure provide a semiconductor structure including a substrate, an isolation layer over the substrate, an epitaxial layer over the substrate and covering the isolation layer, and deep trench isolation extending downward into the epitaxial layer and connecting to the isolation layer. The isolation layer mentioned above is in the second region of the semiconductor structure but does not extend into the first region of the semiconductor structure. The semiconductor structure also includes a first element in the first region and a second element in the second region. Furthermore, the substrate mentioned above contains dopants, which may serve as the drain region of the first element. The second element is in an isolation region defined by the above mentioned deep trench isolation and the above mentioned isolation layer.

Some embodiments of the present disclosure also provide a method of manufacturing a semiconductor structure, including providing a substrate; forming an isolation layer over the substrate mentioned above, wherein the isolation layer mentioned above is in the second region of the semiconductor structure but does not extend into the first region of the semiconductor structure; forming an epitaxial layer over the substrate mentioned above and covering the isolation layer mentioned above; forming a deep trench isolation extending downward into the epitaxial layer, and the deep trench isolation mentioned above is connected to the isolation layer mentioned above; forming the first element in the first region, and the substrate mentioned above serves as the drain region of the first element mentioned above; and forming the second element in the second region mentioned above, and the second element is in an isolation region defined by the deep trench isolation mentioned above and the isolation layer mentioned above.

### BRIEF DESCRIPTION OF THE FIGURES

FIG. 1 is a schematic cross-sectional view of a semiconductor structure at an intermediate manufacturing stage according to some embodiments of the present disclosure.

FIGS. 2A, 2B, 2C, 2D, 2E, 2F, and 2G are partial cross-sectional schematic figures of a semiconductor structure in multiple intermediate manufacturing stages according to some embodiments of the present disclosure.

FIG. 3 illustrates a schematic cross-sectional view of a semiconductor structure at an intermediate manufacturing stage in some other embodiments of the present disclosure.

FIGS. 4A, 4B, 4C, 4D, 4E, 4F, and 4G are schematic cross-sectional views of a semiconductor structure at an intermediate manufacturing stage according to some embodiments of the present disclosure.

FIG. 5 is a schematic cross-sectional view of a semiconductor structure at an intermediate manufacturing stage according to some embodiments of the present disclosure.

FIGS. 6A and 6B are partially enlarged views of the semiconductor structure in FIG. 5.

### DETAILED DESCRIPTION OF THE INVENTION

The following disclosure provides numerous embodiments or examples for implementing different elements of the provided semiconductor elements. Specific examples of elements and arrangements are described below to simplify the present disclosure. Of course, these are only examples and are not intended to limit the present invention. For example, if the description refers to a first element being formed on a second element, unless otherwise specifically excluded, the first element and the second element may be in direct contact or may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “under”, “underlying”, “over”, “overlying”, “above”, and the like, may be used herein for ease of description to describe one element's or feature's relationship to another element(s) or feature(s) as illustrated in the figures. These spatially relative terms are intended to encompass different orientations of the device in use or operation in addition to the orientation depicted in the figures. The device may be otherwise oriented (rotated 90 degrees or at other orientations) and the spatially relative terms used herein may likewise be interpreted accordingly.

Some variations of the embodiments are described below. Similar numeral references are used to identify similar elements in the various figures and illustrated embodiments. It will be appreciated that additional steps may be provided before, during, and after the method, and some of the recited steps may be replaced or deleted for other embodiments of the method.

The present disclosure provides semiconductor structures and methods of manufacturing the same. Through the isolation structures proposed in the embodiments, such as configurations of localized isolation layers and deep trench isolation elements, multiple different types of structures may be integrated on the same substrate (such as a wafer). In particular, it is possible to integrate multiple semiconductor elements with different driving current directions. In particular, multiple semiconductor elements with different driving current directions may be integrated. Through the partially disposed isolation structure illustrated in the embodiment, the semiconductor element provided may have excellent electrical performance. Furthermore, manufacturing methods of the semiconductor structure illustrated in the embodiments integrate different types of semiconductor elements on the same substrate by a simple process, thereby lowering expensive manufacturing costs.

Applications of embodiments include integrating multiple semiconductor elements operating with different current directions on a single substrate. The above-mentioned semiconductor elements are, for example, metal-oxide-semiconductor (MOS) elements, including complementary metal-oxide-semiconductor (CMOS) elements, lateral-diffused metal-oxide-semiconductor (LDMOS) elements, double-diffused metal-oxide-semiconductor (DMOS) elements, vertical-diffused metal-oxide-semiconductor (VDMOS) elements, or other MOS elements. For example, VDMOS elements with a vertical current direction and LDMOS elements, CMOS elements, or other semiconductor elements with a horizontal current direction, may be integrated on the same substrate. However, the present disclosure is not limited to the above elements.

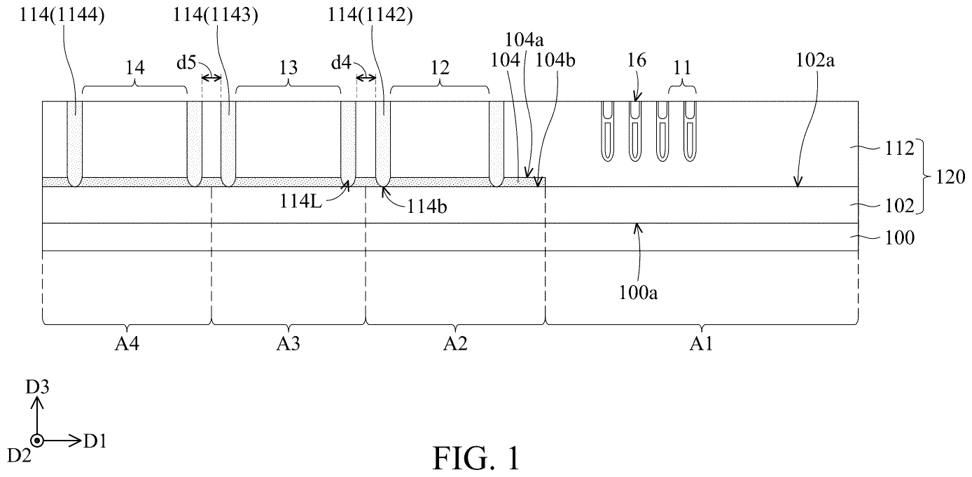

FIG. 1 is a schematic cross-sectional view of a semiconductor structure 1 at an intermediate manufacturing stage in accordance with some embodiments of the present disclosure. According to embodiments, multiple semiconductor elements of different types can be integrated on a substrate 100 by forming a locally extended isolation layer over the substrate, such as a local silicon on the insulator (SOI) layer. Forming a deep trench isolation connected to the isolation layer to form an isolation region to provide a disposing region for semiconductor elements with horizontal operating current, while semiconductor elements with vertical operating current may be placed in a region outside the isolation layer.

According to an embodiment, at least one semiconductor element with a vertical current direction and at least one semiconductor element with a horizontal current direction are integrated on the substrate 100. This example integrates a semiconductor element with a vertical current direction and three semiconductor elements with a horizontal current direction.

As shown in FIG. 1, according to the example illustrated in FIG. 1, the first element 11, the second element 12, the third element 13, and the fourth element 14 are respectively provided in the first region A1, the second region A2, the third region A3 and the fourth region A4 in the semiconductor structure 1 to form a semiconductor structure 1. Wherein, the first element 11, the second element 12, the third element 13, and the fourth element 14 are laterally (e.g., in the first direction D1) separated.

In this example, the first element 11 is a vertical metal oxide semiconductor element, such as a VDMOS element, in which a split trench gate (SGT) structure is used as gate structure 16 of VDMOS elements are described below as an example, but the present disclosure is not limited thereto. In some other embodiments, the first element 11 may also include a general trench gate structure. The second element 12, the third element 13, and the fourth element 14 are non-vertical metal oxides semiconductor elements, such as NMOS elements, LDPMOS elements, and LDNMOS elements respectively. However, the semiconductor elements that may be integrated in the present disclosure are not limited to the types mentioned above.

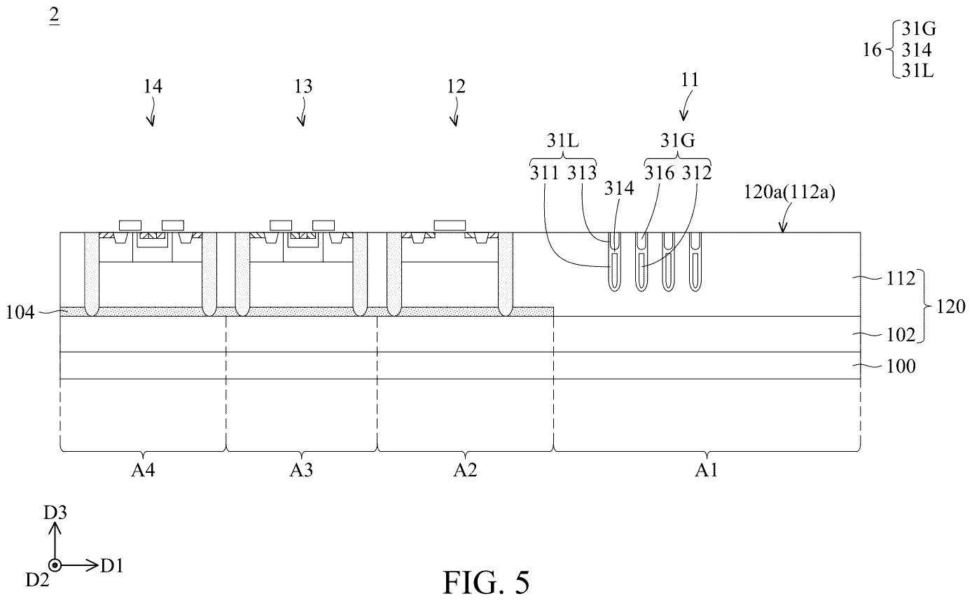

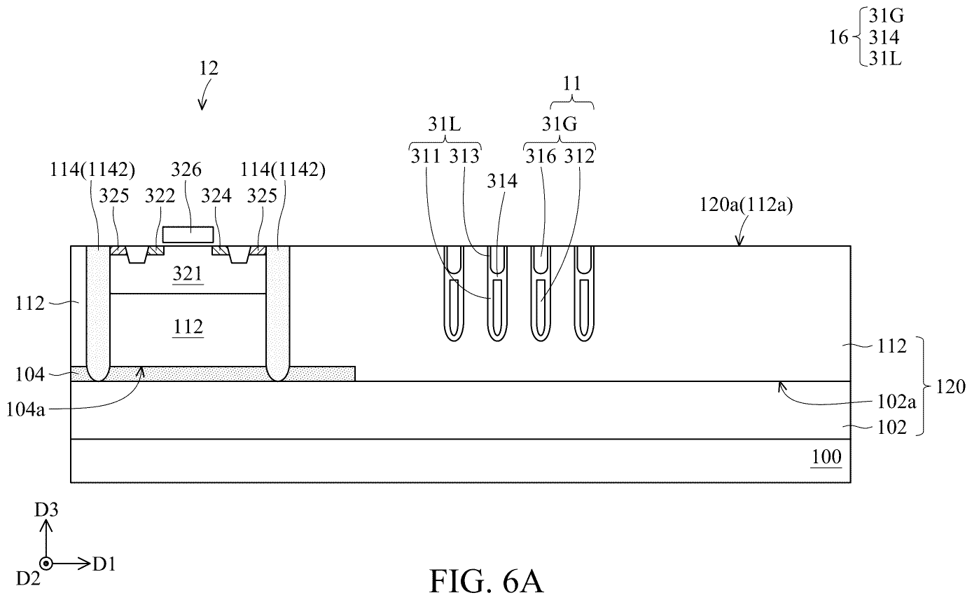

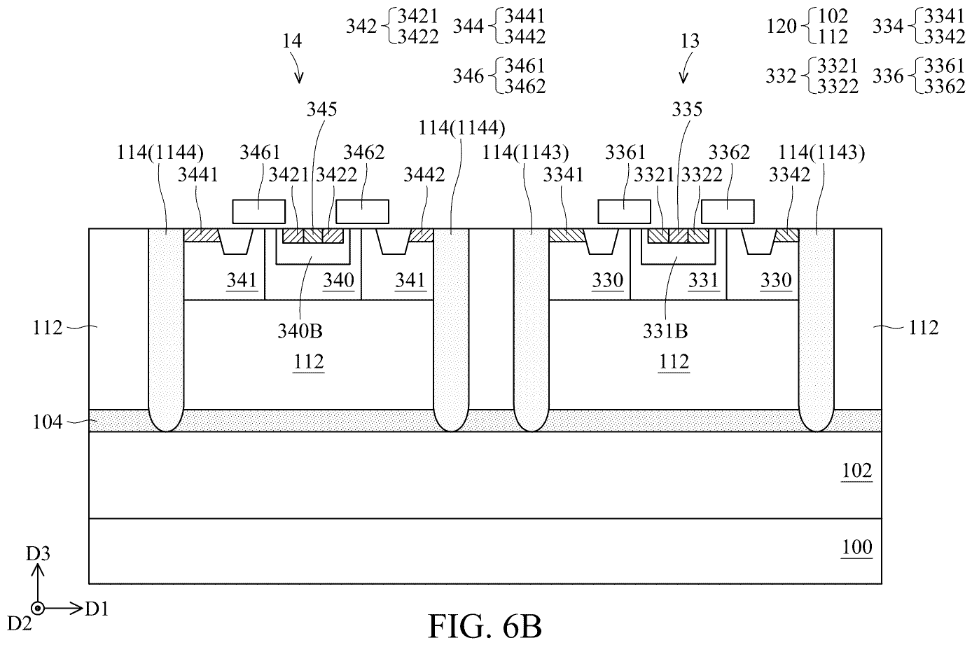

Furthermore, to clearly illustrate the content of the embodiment, the detailed structure and description of these configured elements may be omitted in FIG. 1. Some applicable configurations of the first element 11 to the fourth element 14 and related elements will be provided below (e.g., referring to FIGS. 5, 6A, and 6B) as illustrative but non-limiting descriptions.

According to some embodiments, the semiconductor structure 1 further includes an epitaxial layer 120 and an isolation layer 104 over the substrate 100, and the isolation layer 104 partially extends into the epitaxial layer 120. As shown in FIG. 1, the isolation layer 104 is outside the first region A1. That is, the isolation layer 104 is partially formed over the substrate 100 and is separated from the substrate 100. For example, the isolation layer 104 extends continuously (e.g. along the first direction D1) in the second region A2, the third region A3, and the fourth region A4, but does not extend into the first region A1. Furthermore, although the cross-section in FIG. 1 illustrates that the elongated isolation layer 104 extends in the first direction D1, when viewed from the top of substrate 100 (not shown), the partially disposed isolation layer 104 also extends in the second direction D2.

According to some embodiments, the material of isolation layer 104 includes a single layer or multiple layers of insulating material, such as silicon oxide, germanium oxide, other suitable semiconductor oxide materials, or a combination thereof. Furthermore, the isolation layer 104 may be doped with appropriate dopants or be dopant-free. In some non-limiting examples, isolation layer 104 is a silicon oxide layer.

In some embodiments, the substrate 100 is a substrate doped with a high concentration of a first conductive type dopant, such as a silicon wafer. In an application where a vertical metal oxide semiconductor element is used as the first element 11, since the first region A1 does not include the isolation layer 104, the substrate 100 with the first conductivity type may be used as the drain region of the first element 11, which allows the driving current to flow in the vertical direction (such as in the third direction D3). In some embodiments, a backside conductor layer (not shown) is also formed under substrate 100 to contact the bottom surface of substrate 100, and the backside conductor layer forms the drain terminal of the first element 11. In some embodiments, the first conductivity type is n-type, such that the substrate 100 is, for example, a highly doped n-type substrate. However, the present disclosure is not limited thereto. In some other embodiments, the first conductivity type may also be the opposite conductivity type (e.g., p-type).

In some embodiments, epitaxial layer 120 has the same conductivity type as substrate 100. In this example, both substrate 100 and epitaxial layer 120 have a first conductivity type, such as (but not limited to) n-type, and the doping concentration of substrate 100 is greater than the doping concentration of the epitaxial layer 120.

Furthermore, the epitaxial layer 120 may be a single-layer or a multi-layer structure. As shown in FIG. 1, in this example, the epitaxial layer 120 includes a first epitaxial material layer 102 and a second epitaxial material layer 112. In some embodiments, the locally disposed isolation layer 104 is on the first epitaxial material layer 102, such as on the top surface 102a of the first epitaxial material layer 102, and the isolation layer 104 extends continuously in the second region A2, the third region A3, and the fourth region A4. The second epitaxial material layer 112 is on the first epitaxial material layer 102 and covers the isolation layer 104. Since the isolation layer 104 of the embodiment is partially disposed, in the first region A1 outside the isolation layer 104, the second epitaxial material layer 112 is in direct contact with the first epitaxial material layer 102.

Generally, the multi-layered epitaxial layer 120 may be used to adjust the loading voltage. The thicker the epitaxial layer 120 is, the higher the loading voltage is. Furthermore, an appropriate structure of the epitaxial layer 120 may also be selected based on the actual application conditions of other features and the epitaxial layer 120. For example, when the doping concentration of substrate 100 is very high, an epitaxial layer 120 having a multi-layer structure (e.g., including a first epitaxial material layer 102 and a second epitaxial material layer 112) is formed. When the doping concentration of substrate 100 is not too high, a single-layer epitaxial layer 120 (e.g., not including the first epitaxial material layer 102) may be formed. Therefore, the epitaxial layer 120 with a single-layer or multi-layer structure may be formed according to actual application conditions, and the disclosure is not particularly limited in this regard.

According to some embodiments, the semiconductor structure 1 further includes a deep trench isolation 114 extending downwardly in the epitaxial layer 120 and connecting to the isolation layer 104. The deep trench isolation 114 extends from the top surface 120a of the epitaxial layer 120 toward the substrate 100, for example, extends along the third direction D3.

In some embodiments, the bottom of deep trench isolation 114 does not extend beyond the bottom of isolation layer 104. In some other embodiments, the bottom of deep trench isolation 114 may extend beyond the bottom of isolation layer 104. Accordingly, the bottom of the deep trench isolation 114 and the bottom of the isolation layer 104 may be on roughly the same horizontal level or may be on different horizontal levels. The present disclosure is not limited thereto and may be appropriately designed and adjusted according to the actual manufacturing process.

In some examples, the deep trench isolation 114 may extend through the second epitaxial material layer 112 to the isolation layer 104, for example, a lower portion of the deep trench isolation 114 may be in or through the isolation layer 104. As shown in FIG. 1, the lower portion 114L of the deep trench isolation 114 extends from the top surface 104a of isolation layer 104 to the bottom surface 104b of isolation layer 104.

It is worth noting that the cross-sectional view of FIG. 1 illustrates that deep trench isolation 114 with two elongated cross-sections (e.g., extending in the third direction D3) are formed in each of the second region A2, the third region A3, and the fourth region A4. However, if viewed from the top of the substrate 100, these deep trench isolation 114 are, for example, a closed ring surrounding the periphery of the subsequently formed elements.

According to some embodiments, the isolation structure formed by the configuration of the locally formed isolation layer 104 and the deep trench isolation 114 may define an isolation region, so that the semiconductor elements (e.g., the second element 12/the third element 13/the fourth element 14) disposed in the isolation region may achieve excellent electrical isolation from the semiconductor elements (e.g., the first element 11) outside the isolation region. Especially in some examples where a VDMOS element is used as the first element 11, the substrate 100 serving as the drain of the first element 11 is connected to a drain operating voltage. In this way, even if the first element 11 is operated, the electrical performance of other integrated elements on the substrate 100 (such as the second element 12/third element 13/fourth element 14 in the isolation region) is not affected.

Furthermore, in some embodiments, the semiconductor structure 1 includes an independently disposed trench isolation 114, which may define different isolation regions when connected to the isolation layer 104. Specifically, as illustrated in FIG. 1, the semiconductor structure 1 includes a first deep trench isolation 1142, a second deep trench isolation 1143, and a third deep trench isolation 1144 connected to the isolation layer 104, and these deep trench isolations are separated by an appropriate distance in the lateral direction (such as in the first direction D1). The second element 12 is in an isolation region defined by the first deep trench isolation 1142 and isolation layer 104, wherein the first deep trench isolation 1142 is, for example, closely surrounding the periphery of the second element 12. The third element 13 is in the isolation region defined by the second deep trench isolation 1143 and the isolation layer 104, wherein the second deep trench isolation 1143 is, for example, closely surrounding the periphery of the third element 13. The fourth element 14 is in the isolation region defined by the third deep trench isolation 1144 and the isolation layer 104, wherein the third deep trench isolation 1144 is, for example, closely surrounding the periphery of the fourth element 14.

Furthermore, the first deep trench isolation 1142 and the second deep trench isolation 1143 are separated laterally by a distance d4, for example. The second deep trench isolation 1143 and the third deep trench isolation 1144 are laterally separated by a distance d5, for example. The distance d4 and the distance d5 may be the same or different, and their actual values may be appropriately selected and adjusted according to the elements required for integration in the application.

Furthermore, in an example in which a vertical double-diffused metal oxide semiconductor (VDMOS) element is used as the first element 11, the bottom of the gate structure 16 (such as a separated trench gate structure) may be higher or lower than the isolation layer 104, or roughly at the same horizontal position as the isolation layer 104, which is not particularly limited by the present disclosure. Generally, the closer the bottom of the gate structure 16 is to the substrate 100 serving as the drain region (having a dopant of the first conductivity type (e.g., n-type)), the better the electrical performance of the VDMOS element may be. Therefore, the depth of the gate structure 16 may adjust the vertical current of the VDMOS. However, the bottom surface of the gate structure 16 of the VDMOS element is not in contact with substrate 100 serving as the drain region, that is, it needs to be separated from substrate 100 by a distance. In addition, in some embodiments in which horizontal elements such as N/PMOS and LDMOS elements are used as the second element 12, the third element 13, and the fourth element 14, not only do these elements achieve excellent electrical isolation from each other through the configuration of the locally provided isolation layer 104 and the deep trench isolation 114, the farther the second element 12, the third element 13 and the fourth element 14 are from the substrate 100, the impact of the conductive substrate 100 (such as an n-type substrate) on horizontal MOS elements such as the second element 12, the third element 13 and the fourth element 14 may be reduced to the greater extent.

The following is an example of two methods of forming an isolation structure (including a local isolation layer 104 and deep trench isolation 114) over a substrate according to some embodiments of the present disclosure with reference to the figures. It should be noted that the following relevant details are for illustrative purposes only and are not intended to place limitations on the present disclosure. Furthermore, other known methods may also be applied to fabricate the isolation structures of embodiments.

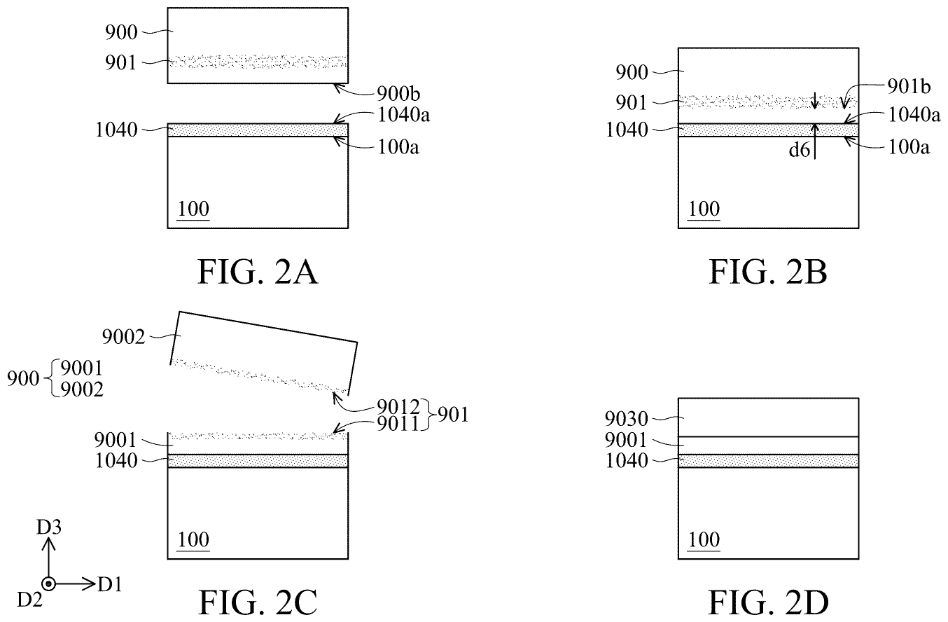

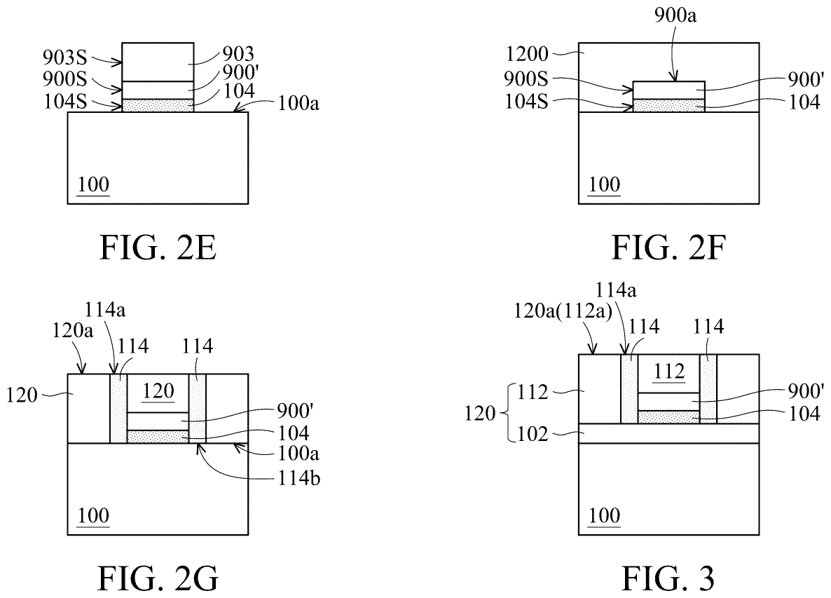

FIGS. 2A-2G are partial cross-sectional schematic figures of a semiconductor structure in multiple intermediate manufacturing stages according to some embodiments of the present disclosure. In this example, smart cut technology and a single epitaxial layer 120 are used for illustrative (not limiting) descriptions.

Refer to FIG. 2A. According to some embodiments, a substrate 100 and a base material 900 are provided. The substrate 100 is, for example, a silicon wafer. Furthermore, an oxide layer, such as a silicon-containing oxide layer 1040, is formed on the top surface 100a of the substrate 100. In some examples, a silicon-containing oxide layer 1040, such as silicon dioxide (SiO₂), may be isotropically formed on the top surface 100a of the substrate 100 by an oxidation process. In some embodiments, the oxidation process may be thermal oxidation, radical oxidation, or other suitable processes.

In some embodiments, the base material 900 is, for example, a donor wafer. There is a weakened layer 901 in the base material 900, which defines the position of the subsequent peeling portion of the base material 900. For example, a hydrogen ion implantation layer is formed in the base material 900 by hydrogen ion implantation technology.

Afterwards, refer to FIG. 2B. According to some embodiments, the silicon-containing oxide layer 1040 on the substrate 100 is bonded with the base material 900. For example, the bonding may be completed by performing low-temperature annealing on the substrate 100 and the base material 900. After bonding, the silicon-containing oxide layer 1040 is between the base material 900 and the substrate 100.

Furthermore, in some embodiments, after the silicon-containing oxide layer 1040 is bonded with the base material 900, there is still a portion of the base material 900 between the weakened layer 901 containing hydrogen ions and the silicon-containing oxide layer 1040, and this portion has approximately, for example, the same thickness. That is, there is no direct contact between the weakened layer 901 and the silicon-containing oxide layer 1040. As shown in FIG. 2B, there is a distance d6 between the bottom surface 901b of the weakened layer 901 and the top surface 1040a of the silicon-containing oxide layer 1040 (in the third direction D3). This distance d6 remains substantially equal in the first direction D1.

After that, refer to FIG. 2C. According to some embodiments, a smart cut process, such as a medium-temperature annealing process, is performed on base material 900 and substrate 100 to peel off a portion of base material 900. A portion of the material from base material 900 may remain over substrate 100 by the smart cut process.

Since a weakened region, such as the weakened layer 901, may be generated in the base material 900 by hydrogen ions implantation, during the smart cut process, the weakened layer 901 is peeled off to remove a portion 9002 of the base material 900. As illustrated in FIG. 2C, the weakened layer 901 is separated, for example, along the middle part and divided into an upper layer 9012 and a lower layer 9011. The upper layer 9012 is, for example, the bottom surface of the removed portion 9002 of the base material 900. The lower layer 9011 is, for example, the top surface of the remaining portion 9001 of the base material 900.

After the peeling off process is performed, the remaining portion 9001 of the base material 900 is transferred to the top of the substrate 100, for example, on the silicon-containing oxide layer 1040 and covering the silicon-containing oxide layer 1040. The remaining portion 9001 of the base material 900 may be referred to as a donor layer 9001 below. In some examples, the base material 900 is, for example, a silicon-containing substrate, and the donor layer 9001 is, for example, a donor silicon layer.

Furthermore, in some embodiments, after the peeling step (e.g., by smart cut process), a thermal process may be optionally performed on the silicon-containing oxide layer 1040 to increase the density of the oxide layer material. In some embodiments, the thermal process mentioned above may be a rapid thermal annealing (RTA) process.

Afterwards, refer to FIG. 2D. According to some embodiments, a mask material 9030 is formed over the donor layer 9001. The mask material 9030 is, for example, single or multiple layers of hard mask material. To simplify the figure, a single layer of mask material 9030 is illustrated as an example in the figure. Mask material 9030 may include an oxide, such as silicon dioxide (SiO₂). In some examples, an oxide hard mask material may be deposited over donor layer 9001.

Refer to FIG. 2E. According to some embodiments, a suitable photolithographic patterning process may be used to define the position of isolation layer 104 locally disposed on substrate 100.

In some examples, a patterned photoresist (patterned PR) (not shown) corresponding to the position of the isolation layer 104 may be formed on the mask material 9030 (e.g., oxide hard mask material). For example, the patterned photoresist has a plurality of openings to expose the top surface of the underlying mask material 9030.

Furthermore, the patterned photoresist mentioned above may be formed by, for example, photoresist coating (e.g., spin coating), soft baking, mask alignment, exposure, post-exposure baking, photoresist development, cleaning and drying (e.g., hard baking), other suitable processes, or a combination thereof to form a patterned photoresist with openings.

Afterwards, the mask material 9030 is etched according to the patterned photoresist to form a mask (e.g., an oxide hard mask) 903. This mask 903 exposes the top surface of the underlying donor layer 9001.

After the mask 903 is formed, the patterned photoresist is then removed.

Afterwards, portions of the donor layer 9001 and portions of the silicon-containing oxide layer 1040 are removed according to the pattern of mask 903. For example, portions of donor layer 9001 and silicon-containing oxide layer 1040 that are not covered by mask 903 are removed. The remaining portion of the donor layer 9001 forms a donor portion 900′, such as a donor silicon portion. The remaining portion of the silicon-containing oxide layer 1040 forms the isolation layer 104 of the embodiment.

In some embodiments, as illustrated in FIG. 2E, the side surface 903S of the mask 903, the side surface 900S of the donor portion 900′, and the side surface 104S of the isolation layer 104 are substantially coplanar.

After forming the donor portion 900′ and the isolation layer 104 of the embodiment, mask 903 may be removed by an ashing process, a wet etching process (such as acid etching), or other suitable processes. After removing the mask 903, a cleaning process may be optionally performed to remove residues.

Refer to FIG. 2F. According to some embodiments, an epitaxial material 1200 is formed over the substrate 100, wherein the epitaxial material 1200 covers the donor portion 900′ and the isolation layer 104.

In some examples, the epitaxial material 1200 is excessively formed over the substrate 100, and the epitaxial material 1200 covers the top surface 900a and the side surface 900S of the donor portion 900', and covers the side surface 104S of the isolation layer 104.

Furthermore, a planarization process may be optionally performed on the epitaxial material 1200 to make it a flat top surface. The planarization process mentioned above is, for example, a chemical mechanical polishing (CMP) process, a mechanical polishing process, an etch-back process, other suitable processes, or a combination thereof. It is worth noting that after the planarization process, the epitaxial material 1200 of the embodiment is still excessively formed on the top surface 900a of the donor portion 900′.

After that, refer to FIG. 2G. According to some embodiments, deep trench isolation 114 is formed in epitaxial layer 120, with the bottom of the deep trench isolation 114 connected to the isolation layer 104. The position of the deep trench isolation 114 may be defined by a suitable photolithography patterning process.

In some examples, a mask (not shown) may be formed over the epitaxial material 1200, and the mask has a plurality of openings corresponding to the positions of the deep trench isolations 114 to be formed. In some embodiments, the mask is, for example, a patterned photoresist formed of photoresist material. In some other embodiments, the mask material may be a hard mask (HM) composed of an oxide layer and a nitride layer. In some examples in which the patterned photoresist is used as a mask, the photolithographic patterning process described above includes photoresist coating (e.g., spin coating), soft bake, mask alignment, exposure, post-exposure baking, photoresist development, cleaning and drying (e.g., hard baking), other suitable processes, or a combination thereof to form the opening of the mask.

Afterwards, a portion of the epitaxial material 1200 is removed according to the opening of the mask to form deep trenches (not shown) connected to the isolation layer 104. The remaining portion of the epitaxial material 1200 forms the epitaxial layer 120. Therefore, in this example, the deep trenches expose the epitaxial layer 120, the silicon donor portion 900′, and the isolation layer 104 from top to bottom at the sidewalls adjacent to the isolation layer 104. Afterwards, suitable materials are filled into these deep trenches, and portions of the material are removed by an appropriate planarization process to form deep trench isolation 114 in the epitaxial layer 120.

The planarization process mentioned above is, for example, a chemical mechanical polishing (CMP) process, a mechanical polishing process, an etch-back process, other suitable processes, or a combination thereof. According to some embodiments, after the planarization process, the top surface 114a of the deep trench isolation 114 is substantially coplanar with the top surface 120a of the epitaxial layer 120.

In some embodiments, each deep trench isolation 114 includes an insulating material. In some embodiments, each deep trench isolation 114 includes an insulating material (not shown) and a conductive material (not shown), in which the insulating material covers the side walls and bottom of the conductive material. The insulating materials mentioned above include but are not limited to, silicon oxide, germanium oxide, hafnium oxide, zirconium oxide, aluminum oxide, aluminum hafnium dioxide alloy, silicon hafnium dioxide, silicon hafnium oxynitride, tantalum hafnium oxide, titanium hafnium oxide, zirconium hafnium oxide, other suitable materials, or combinations thereof. In some embodiments, the conductive material mentioned above includes amorphous silicon, polycrystalline silicon, other suitable materials, or combinations thereof. In some examples, the insulating material includes silicon oxide and the conductive material includes polycrystalline silicon.

Accordingly, after the deep trench isolation 114 connected to isolation layer 104 is formed, the production of the isolation structure of the embodiment is completed.

Although the single-layer epitaxial layer 120 is used as an example with reference to FIGS. 2A-2G, the present disclosure is not limited thereto. In some embodiments, epitaxial layer 120 may also include multiple layers of epitaxial material.

FIG. 3 is a partial cross-sectional schematic figure of a semiconductor structure at an intermediate manufacturing stage in some other embodiments of the present disclosure. Elements in FIG. 3 that are identical or similar to those in FIG. 2G have the same or similar reference numbers.

As shown in FIG. 3, the epitaxial layer 120 includes a first epitaxial material layer 102 and a second epitaxial material layer 112, and a locally disposed isolation layer 104 is on the first epitaxial material layer 102, for example, on the top surface 102a of the first epitaxial material layer 102. Furthermore, in the example of FIG. 3, the bottom surface of the deep trench isolation 114 connected to the isolation layer 104 stops, for example, on the top surface 102a of the first epitaxial material layer 102. According to some embodiments, the top surface 114a of the deep trench isolation 114 is substantially coplanar with the top surface 112a of the second layer of epitaxial material 112.

The structure shown in FIG. 3 may be formed by referring to the manufacturing method of FIGS. 2A-2G above. However, the difference is that the example in FIG. 3 is to first form the first epitaxial material layer 102 on the substrate 100, and then form the silicon-containing oxide layer 1040 on the top surface of the first epitaxial material layer 102 (may refer to FIG. 2A pictures and related illustrations). The substrate 100 is then bonded with the base material 900 including the weakened layer 901 (may refer to FIG. 2B and related illustrations). After that, a smart cut process is performed to peel off the weakened layer 901 to remove a portion 9002 of the base material 900, and the remaining portion 9001 of the base material 900 is on the silicon-containing oxide layer 1040 (refer to FIG. 2C and related illustrations). Afterwards, a mask 903 is formed, and the position of the isolation layer 104 is defined according to the pattern of mask 903 (please refer to FIGS. 2D and 2E and related illustrations). Afterwards, a second epitaxial material layer 112 is formed excessively on the first epitaxial material layer 102, wherein the second epitaxial material layer 112 covers the donor portion 900′, the isolation layer 104, and the first epitaxial material layer 102, and forms a deep trench isolation 114 in the second epitaxial material layer 112 (may refer to FIGS. 2F and 2G and related illustrations). The inner sidewall of the deep trench isolation 114 contacts, for example, the excess portion of the second epitaxial material layer 112, the donor portion 900′, and the isolation layer 104 from top to bottom in sequence.

In this example, as illustrated in FIG. 3, the first epitaxial material layer 102 and the second epitaxial material layer 112 may be collectively referred to as the epitaxial layer 120. Therefore, the isolation layer 104 is also formed in the epitaxial layer 120, and a first epitaxial material layer 102 is also included between the isolation layer 104 and the substrate 100.

According to the above-mentioned manufacturing method, the locally extended isolation layer 104 and the deep trench isolation 114 connected to the isolation layer 104 may be formed in some regions of the semiconductor structure, to define a settable region of the semiconductor elements with driving current in a horizontal direction. The region without the isolation layer 104 is used to dispose of semiconductor elements with driving current in a vertical direction.

In addition to the above-mentioned manufacturing method using the smart cut process, semiconductor structures may also be manufactured by other methods, and this disclosure is not limited thereto. Another possible preparation method is proposed below.

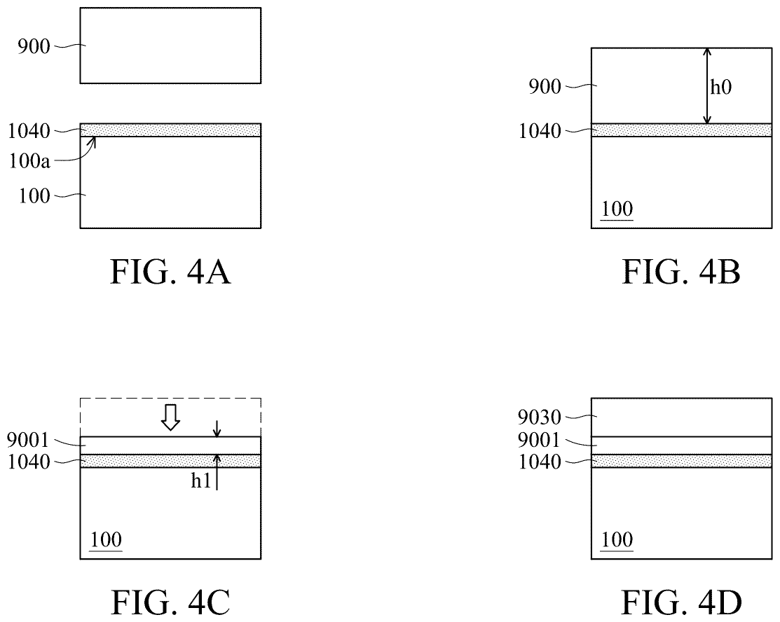

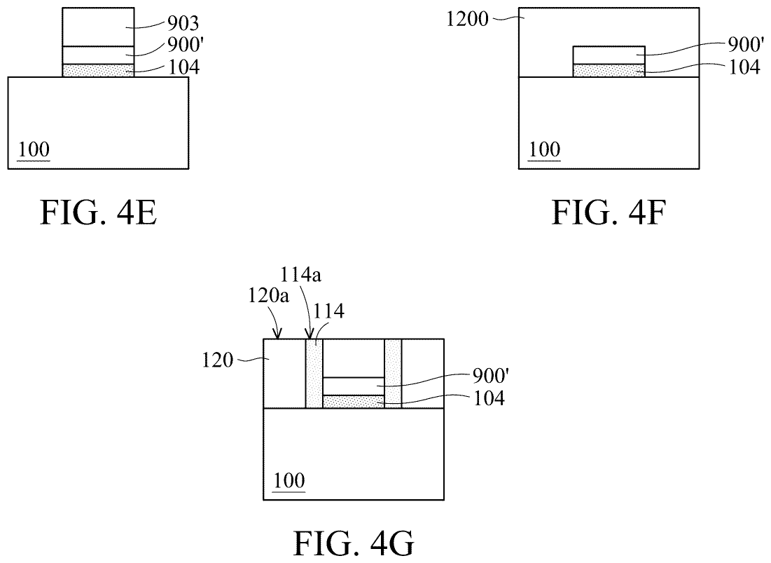

FIGS. 4A-4G are partial cross-sectional schematic figures of a semiconductor structure in multiple intermediate manufacturing stages according to some embodiments of the present disclosure. The same or similar elements in FIGS. 4A-4G as those in FIGS. 2A-2G refer to the same or similar numeral references. Furthermore, in this example, the formation of a single epitaxial layer 120 is used as an illustrative (but non-limiting) description.

Refer to FIG. 4A. According to some embodiments, a substrate 100 and a base material 900 are provided. A silicon-containing oxide layer 1040 is formed on the top surface 100a of the substrate 100.

Regarding the configuration, materials, and manufacturing methods of substrate 100, the silicon-containing oxide layer 1040, and base material 900 in FIG. 4A, please refer to the relevant descriptions of substrate 100, the silicon-containing oxide layer 1040, and base material 900 given with reference to FIG. 2A. These will not be repeated here. It is worth noting that the configuration in this example does not have a weakened layer within the base material 900.

After that, refer to FIG. 4B. According to some embodiments, the silicon-containing oxide layer 1040 on substrate 100 is directly bonded to base material 900. After bonding, the silicon-containing oxide layer 1040 is between the base material 900 and the substrate 100.

After that, refer to FIG. 4C. According to some embodiments, a portion of the base material 900 is removed such that the remaining portion 9001 of the base material 900 is on the silicon-containing oxide layer 1040. The remaining portion 9001 of the base material 900 may also be referred to as the donor layer 9001. In this example, portions of the base material 900 may be removed by performing a thinning process on the base material 900. The thinning process mentioned above may include a chemical mechanical polishing process, a mechanical polishing process, an etching process, other suitable processes, or a combination of the foregoing processes.

The stopping point of the thinning process mentioned above determines the top surface position of the donor layer 9001. In this example, after the thinning process, the initial thickness h0 of the base material 900 (FIG. 4B) is reduced to the thickness h1 of the donor layer 9001 (FIG. 4C). The donor layer 9001 has a substantially uniform thickness h1.

After that, refer to FIG. 4D. According to some embodiments, a mask material 9030 is formed over the donor layer 9001. The mask material 9030 is, for example, single or multiple layers of hard mask material. To simplify the figure, a single layer of mask material 9030 is illustrated as an example in FIG. 4D. In some examples, the mask material 9030 is, for example, an oxide hard mask material, such as silicon dioxide (SiO₂).

After that, refer to FIG. 4E. According to some embodiments, a suitable photolithographic patterning process may be used to define the position of isolation layer 104 locally disposed on substrate 100.

In some examples, a patterned photoresist (not shown) corresponding to the position of the isolation layer 104 may be formed on the mask material 9030. The mask material 9030 is etched according to the patterned photoresist to form a mask 903, the patterned photoresist is removed, and the underlying donor layer 9001 and the silicon-containing oxide layer 1040 are etched according to the mask 903 to form the donor portion 900′ and the isolation layer 104.

Regarding the arrangement, materials, and manufacturing method of the patterned photoresist, mask 903, donor portion 900′ and the isolation layer 104 in FIG. 4E, please refer to the relevant description of the patterned photoresist, mask 903, donor portion 900′ and the isolation layer 104 in FIG. 2E above. These will not be repeated here.

After that, refer to FIG. 4F. According to some embodiments, an epitaxial material 1200 is formed excessively over the substrate 100, wherein the epitaxial material 1200 covers the donor portion 900′ and the isolation layer 104.

Regarding the configuration, materials, and manufacturing method of the epitaxial material 1200 in FIG. 4F, please refer to the relevant description of the epitaxial material 1200 in FIG. 2F above. These will not be repeated here.

After that, refer to FIG. 4G. According to some embodiments, deep trench isolation 114 is formed in the epitaxial layer 120, with the bottom of the deep trench isolation 114 connected to the isolation layer 104.

In some examples, deep trench isolation 114 may be formed by a suitable photolithographic patterning process and deposition process. For example, a mask having a plurality of openings is formed over the epitaxial material 1200, portions of the epitaxial material 1200 are removed through the openings to form deep trenches, and appropriate materials are filled in the deep trenches, thereby forming deep trench isolation 114. For details of these processes, please refer to the relevant descriptions in FIG. 2G above which will not be repeated here.

Furthermore, regarding the configuration, material, and manufacturing method of the deep trench isolator 114 in FIG. 4G, please refer to the relevant description of the deep trench isolator 114 in FIG. 2G above, and will not be described further here.

According to the above, after forming the deep trench isolation 114 connected to the isolation layer 104, the manufacture of the isolation structure of the embodiment can be completed.

In some applications, one or more semiconductor elements with driving current in a horizontal direction may be integrated into an isolation region defined by the deep trench isolation 114 and the isolation layer 104 over the substrate 100, and the semiconductor elements outside the isolation layer 104, while the region outside the isolation layer 104 may be integrated to form one or more semiconductor elements with driving current in a vertical direction. The following is an example of one of the semiconductor structures 2 used in element integration applications, which integrates VDMOS elements, N/P-type MOS elements, P-type LDMOS elements, and N-type LDMOS elements. However, the semiconductor elements that may be integrated into the present disclosure are not limited to the above combinations.

FIG. 5 is a schematic cross-sectional view of a semiconductor structure 2 at an intermediate manufacturing stage according to some embodiments of the present disclosure. FIGS. 6A and 6B are partially enlarged views of the semiconductor structure 2 in FIG. 5. The same or similar elements in FIGS. 5, 6A, and 6B as in FIG. 1 use the same or similar numeral references, and reference can be made to the content of these elements in the above embodiments, which will not be repeated in this example.

As shown in FIG. 5, in some embodiments, the semiconductor structure 2 includes a plurality of VDMOS elements disposed in the first region A1 as the first element 11, and in the example, a separated trench gate (SGT) structure is used as the gate structure 16 of the VDMOS elements, but the disclosure is not limited thereto.

In some embodiments, the semiconductor structure 2 further includes an N/P type MOS element disposed in the second region A2 as an example of the second element 12; a P-type LDMOS element is provided in the third region A3 as an example of the third element 13; and an N-type LDMOS element is provided in the fourth region A4 as an example of the fourth element 14. According to some embodiments, the isolation layer 104 in the semiconductor structure 2 is locally formed over the substrate 100, for example, continuously extending along the first direction D1 in the second region A2, the third region A3, and the fourth region A4.

Refer to FIGS. 5 and 6A. According to some embodiments, in an example in which a VDMOS element is used as the first element 11, each first element 11 includes a gate structure 16 and a heavily doped portion (not shown). The heavily doped portion is adjacent to one side of gate structure 16 and extends downward from the top surface 120a of the epitaxial layer 120. This heavily doped portion may serve as the source region of the first element 11. The substrate 100 (e.g., n-type) serves as the drain region of the first element 11.

In some embodiments, the heavily doped portion (not shown) serving as the source region of the first element 11 and the epitaxial layer 120 have the same conductivity type, and the doping concentration of this heavily doped portion is greater than the doping concentration of the epitaxial layer 120.

In some embodiments, the substrate 100 and the epitaxial layer 120 serving as the drain region of the first element 11, and the heavily doped portion serving as the source region have a first conductivity type, such as (but not limited to) n-type. Furthermore, the doping concentration of the substrate 100 is greater than the doping concentration of the epitaxial layer 120.

In some embodiments, the position of the gate structure 16 of the first element 11 may be defined by a suitable photolithographic patterning process. For example, a mask is first formed above the epitaxial layer 120, and a trench (not shown) is formed in the epitaxial layer 120 (e.g., in the second epitaxial material layer 112) through the mask; an insulating layer 311 and a dielectric layer 313 are then respectively formed on the upper and lower portions of the sidewalls of the trench, and a bottom gate 312 and a top gate 316 separated up-and-down by an insulating portion 314 are formed in the trench to form the gate structure 16.

The insulating layer 311 and the dielectric layer 313 collectively form a lining layer 31L in the trench, and the bottom gate 312 and the top gate 316 collectively form the gate 31G. The gate structure 16 in this example includes, for example, a liner layer 31L, an insulating portion 314, and a gate 31G. However, the present disclosure is not limited to this illustrative structure.

According to some examples, the mask is a patterned photoresist formed of photoresist material. In some other embodiments, the mask material may be a hard mask (HM) composed of an oxide layer and a nitride layer. In some examples in which the patterned photoresist is used as a mask, the photolithographic patterning process described above includes photoresist coating (e.g., spin coating), soft bake, mask alignment, exposure, post-exposure baking, photoresist development, cleaning and drying (e.g., hard baking), other suitable processes, or a combination thereof to form multiple openings of the mask (not shown). These openings expose the top surface 120a of the epitaxial layer 120. In this example, the openings expose the top surface 112a of the second epitaxial material layer 112.

According to some examples, after the mask mentioned above is formed, one or more etching processes are performed through the openings of the mask to remove portions of the epitaxial layer 120, thereby forming trenches in the epitaxial layer 120. The etching process mentioned above includes, for example, a dry etching process, a wet etching process, a plasma etching process, a reactive ion etching process, other suitable processes, or a combination thereof.

In some examples, the trench is positioned to correspond to and below the opening of the mask. Thus, the trench formed is, for example, continuous with the opening and communicates with the opening. In some embodiments, the depth of trench in the epitaxial layer 120 (e.g. along the third direction D3) may be greater than, less than, or equal to the depth of the deep trench isolation 114 (e.g. along the third direction D3) in the epitaxial layer 120. The size, shape, and position of the openings and trenches of the mask depend on the size, shape, and position of the gate structure 16 to be formed in actual applications, and are not limited herein.

According to some examples, after the trenches are formed in the epitaxial layer 120, the mask can be removed through an ashing process, a wet etching process (such as acid etching), or other suitable processes. After removing the mask, a cleaning process may be optionally performed to remove residue.

Afterward, according to some examples, a shielding insulating layer is formed on the sidewalls of the trench. The shielding insulating layer is, for example, silicon oxide, germanium oxide, other suitable semiconductor oxide materials, or a combination thereof. Furthermore, an oxidation process may be used to conformally form a shielding insulating layer on the sidewalls and bottom surfaces of the trenches and on the top surface 120a of the epitaxial layer 120. The oxidation process mentioned above may be thermal oxidation, free radical oxidation, or other suitable processes.

In some examples, a thermal process, such as a rapid thermal annealing (RTA) process, may also be optionally performed on the shielding insulating layer to increase the density of the shielding insulating layer.

According to some examples, a bottom gate 312 is formed in a lower portion of the trench, wherein the bottom gate 312 is on the shielding insulating layer. The bottom gate 312 may be a single-layer or multi-layer structure and may be formed of, for example, amorphous silicon, polycrystalline silicon, other suitable conductive materials, or a combination thereof.

In some examples, a gate electrode material (not shown) may be deposited on the shielding insulating layer by a deposition process, and the gate electrode material fills the space outside the shielding insulating layer in the trench. The deposition process mentioned above may be a physical vapor deposition (PVD) process, a chemical vapor deposition (CVD) process, other suitable processes, or a combination thereof. Furthermore, in this example, the gate electrode material may optionally undergo a thermal process, such as an annealing process.

Next, a portion of the gate electrode material is removed to form the bottom gate 312 as illustrated in FIGS. 5 and 6A. For example, excess portions of the deposited gate electrode material may be removed by a planarization process, such as removing portions of the gate electrode material over the top surface 120a of the epitaxial layer 120. The planarization process mentioned above is, for example, a chemical mechanical polishing (CMP) process, a mechanical polishing process, an etching process, other suitable processes, or a combination thereof. After that, the portion of the gate electrode material in the trench is etched back to recess the gate electrode material to a specific depth to form the bottom gate 312 in the trench.

In some examples, bottom gate 312 may optionally include a second conductivity type dopant, such as a p-type dopant. In some examples, the dopant of bottom gate 312 may be boron difluoride (BF₂) or other suitable dopants. The bottom gate 312 that separates the trench gate structure not only reduces the gate-drain capacitance (Cgd) to improve the switching characteristics of the semiconductor element but the bottom gate 312 with the second conductivity type also further enhances the effect of reducing the surface electric field (RESURF).

According to some examples, after the bottom gate 312 is formed, the upper portion of the shielding insulating layer may be removed by an etching process, and the remaining portion of the shielding insulating layer forms an insulating layer 311 on the sidewalls and bottom of the lower portion of the trench. The etching process mentioned above is, for example, a dry etching process, a wet etching process, a plasma etching process, a reactive ion etching process, other suitable processes, or a combination of the above. Furthermore, the top surface of the insulating layer 311 may be higher than the top surface of the bottom gate 312 or may be substantially coplanar with the top surface of the bottom gate 312 with a slight dishing.

Afterward, a dielectric layer 313 is formed on the insulating layer 311 and the bottom gate 312 to serve as a gate dielectric layer for the subsequently formed top electrode 316.

In some examples, a dielectric layer 313 may be conformally deposited by a suitable deposition process to extend from the top surface 120a of the epitaxial layer 120 to the upper portion of the trench and cover the top surface of the insulating layer 311 and the top surface of the bottom gate 312. The dielectric layer 313 does not totally fill the trench. Furthermore, the deposition process mentioned above includes, for example, a PVD process, a CVD process, an atomic layer deposition (ALD) process, other suitable deposition processes, or a combination thereof.

In some examples, the dielectric layer 313 includes, for example, silicon oxide, hafnium oxide, zirconium oxide, aluminum oxide, aluminum hafnium dioxide alloy, silicon hafnium dioxide, silicon hafnium oxynitride, tantalum hafnium oxide, titanium hafnium oxide, zirconium hafnium oxide, other suitable high dielectric constant (high-k) dielectric materials, or a combination thereof. In some examples, dielectric layer 313 is formed of a different material than the underlying insulating layer 311. In some other examples, dielectric layer 313 is formed of the same material as insulating layer 311.

Furthermore, according to some examples, during the formation process of dielectric layer 313, the bottom gate 312 is also oxidized, thereby forming a thicker insulating portion 314 over the bottom gate 312. The insulating portion 314 includes, for example, an insulating oxide. After the top electrode 316 is subsequently formed, the insulating portion 314 is between the bottom gate 312 and the top gate 316 and may be used to electrically isolate the bottom gate 312 and the top gate 316.

Afterwards, according to some examples, a top gate 316 is formed in the upper portion of the trench.

For example, the gate electrode material may be deposited on the dielectric layer 313 by a deposition process and fill the space outside the dielectric layer 313 in the upper portion of the trench. The deposition processes mentioned above include PVD, CVD, other suitable processes, or a combination thereof. Furthermore, the gate electrode material may be optionally subjected to a thermal process, such as an annealing process. Thereafter, the excess portion of the gate electrode material is removed by, for example, a planarization process (including a CMP process, a mechanical polishing process, an etching process, other suitable processes, or a combination thereof) to form the top gate 316.

As shown in FIGS. 5 and 6A, the top gate 316 is on the dielectric layer 313 and is separated from the bottom gate 312 thereunder by an insulating portion 314. Top gate 316 may be a single-layer or multi-layer structure.

In some examples, top gate 316 may be formed of amorphous silicon, polycrystalline silicon, one or more metals, metal nitrides, metal silicides, conductive metal oxides, or a combination thereof. In some examples, the metals mentioned above may include, but are not limited to, molybdenum (Mo), tungsten (W), titanium (Ti), tantalum (Ta), platinum (Pt), or hafnium (Hf). The metal nitrides mentioned above may include, but are not limited to, molybdenum nitride (MoN), tungsten nitride (WN), titanium nitride (TiN), and tantalum nitride (TaN). The metal silicide mentioned above may include but is not limited to tungsten silicide (WSiₓ). The conductive metal oxide mentioned above may include, but is not limited to, ruthenium metal oxide (RuO₂) and indium tin metal oxide (indium tin oxide, ITO).

Furthermore, in some examples, top gate 316 may optionally include dopants with a second conductivity type (e.g., p-type). Furthermore, the materials used to form the top gate 316 and the bottom gate 312 may be the same or different.

Accordingly, the fabrication of some illustrative gate structures 16 is completed, which includes the lining layer 31L, the insulating portion 314, and the gate 31G. The lining layer 31L includes an insulating layer 311 and a dielectric layer 313. The bottom gate 312 and the top gate 316 in the trench may be collectively referred to as gate 31G. The insulating portion 314 is between the bottom gate 312 and the top gate 316. However, the present disclosure is not limited to the gate structure 16 of this example.

In addition, in the example in which a VDMOS element is used as the first element 11, the closer the bottom of the gate structure 16 is to the substrate 100, which has a dopant of the first conductivity type (such as n-type) and serves as the drain region, the more extent the electrical performance of the VDMOS element may be improved. According to some examples, the bottom of gate structure 16 may be close to the bottom surface of the second epitaxial material layer 112 (e.g., close to the isolation layer 104 or substantially equal to the depth of deep trench isolation 114) or extend into the first epitaxial material layer 102, but the gate structure 16 is not in direct contact with substrate 100.

Refer again to FIGS. 5 and 6A. According to some embodiments, in an example in which a PMOS element is used as the second element 12, an N-type well region 321 may be formed in the isolation region defined by the first deep trench isolation 1142 and the isolation layer 104, and heavily doped portions 322, 324 and 325 are formed in the N-type well region 321. These heavily doped portions 322, 324, and 325 may be separated from each other by appropriate distances.

In this example, the heavily doped portion 322 and the heavily doped portion 324 may be respectively the source region and the drain region of a subsequently formed PMOS element (the second element 12). The heavily doped portion 325 is the base region of the PMOS element. Furthermore, in this example, the heavily doped portion 322 and the heavily doped portion 324 have the same conductivity type, such as (but not limited to) p-type. The heavily doped portion 325 and the heavily doped portions 322 and 324 have different conductivity types. The heavily doped portion 325 is, for example (but not limited to) n-type.

Furthermore, in some embodiments, the gate structure 326 of the PMOS element (the second element 12) is formed over the N-type well region 321. The gate structure 326 is on the epitaxial layer 120 and between the heavily doped portion 322 (source region) and the heavily doped portion 324 (drain region). The gate structure 326 includes, for example, a gate dielectric layer (not shown) and a gate electrode over the gate dielectric layer.

Furthermore, in this example, a portion of the epitaxial layer 120, such as a portion of the second epitaxial material layer 112, is also included between the N-type well region 321 and the underlying isolation layer 104 to achieve better electrical isolation between the formed PMOS element (second element 12) and the substrate 100 (e.g., n-type), thereby reducing the possible impact of the substrate 100 on the PMOS element during the operation of first element 11.

Refer to FIGS. 5 and 6B. According to some embodiments, in an example in which a P-type LDMOS element is used as the third element 13, the N-type well region 331 and the P-type well region 330 may be formed in the isolation region defined by the second deep trench isolation 1143 and the isolation layer 104. One of the N-type well region 331 is between the two P-type well regions 330, and the bottom surfaces of the N-type well region 331 and the P-type well region 330 are covered by a portion of the epitaxial layer 120 (e.g., the second epitaxial material layer 112).

The N-type well region 331 and the P-type well region 330 may be formed in the epitaxial layer 120 (such as the second epitaxial material layer 112 in this example) by an ion implantation process. The N-type well region 331 and the P-type well region 330 extend downward from the top surface 120a of the epitaxial layer 120 into the epitaxial layer 120.

According to some examples, the P-type LDMOS element further includes a heavily doped portion 332 (source region), a heavily doped portion 334 (drain region), a heavily doped portion 335 (base region), and a gate structure 336. The heavily doped portions 332 and 334 have the same second conductivity type, such as p-type. The heavily doped portion 335 has a first conductivity type, such as n-type.

More specifically, as illustrated in FIG. 6B, the gate structure 336 includes gate structures 3361 and 3362 spanning the P-type well region 330 and the N-type well region 331.

The heavily doped portion 332 (source region) includes a heavily doped portion 3321 adjacent to the gate structure 3361 and a heavily doped portion 3322 adjacent to the gate structure 3362. The heavily doped portions 3321 and 3322 are in the N-type well region 331.

The heavily doped portion 334 (drain region) includes a heavily doped portion 3341 adjacent to the gate structure 3361 and a heavily doped portion 3342 adjacent to the gate structure 3362. The heavily doped portions 3341 and 3342 are in the two P-type well regions 330 respectively.

The heavily doped portion 335 (base region) is in the N-type well region 331 and is disposed between the two heavily doped portions 3321 and 3322 (source region).

Furthermore, according to some examples, an N-type body region (n-body region) 331B is also formed in the N-type well region 331. The heavily doped portion 335 (base region) and the heavily doped portions 3321 and 3322 (source regions) are formed in the N-type body region 331B.

Furthermore, according to some examples, the doping concentration of the N-type well region 331 is smaller than the doping concentration of the heavily doped portion 332 (including 3321 and 3322; source region) and the heavily doped portion 334 (including 3341 and 3342; drain region). The doping concentration of the N-type body region 331B is smaller than the doping concentrations of the heavily doped portion 332 and the heavily doped portion 334.

Furthermore, in this example, a portion of the epitaxial layer 120 is also included between the N-type well region 331 and the P-type well region 330 and the underlying isolation layer 104, such as a portion of the second epitaxial material layer 112, so that the formed P-type LDMOS element (third element 13) is further away from the substrate 100 (for example, n-type), thereby reducing the possible impact of the conductive substrate 100 on the third element 13 during the operation of first element 11.

Refer again to FIGS. 5 and 6B. According to some embodiments, in an example in which an N-type LDMOS element is used as the fourth element 14, the P-type well region 340 and the N-type well region 341 may be formed in the isolation region defined by the third deep trench isolation 1144 and the isolation layer 104. The P-type well region 340 is between two N-type well regions 341, and the bottom surfaces of the P-type well region 340 and the N-type well region 341 are covered by a portion of the epitaxial layer 120 (e.g., the second epitaxial material layer 112).

The N-type well region 341 and the P-type well region 340 may be formed in the epitaxial layer 120 (such as the second epitaxial material layer 112 in this example) by an ion implantation process. The N-type well region 341 and the P-type well region 340 extend downward from the top surface 120a of the epitaxial layer 120 into the epitaxial layer 120.

According to some examples, the N-type LDMOS element further includes a heavily doped portion 342 (source region), a heavily doped portion 344 (drain region), a heavily doped portion 345 (base region), and a gate structure 346. The heavily doped portions 342 and 344 have the same first conductivity type, such as n-type. The heavily doped portion 335 has a second conductivity type, such as p-type.

More specifically, as illustrated in FIG. 6B, gate structure 346 includes gate structures 3461 and 3462 spanning the N-type well region 341 and the P-type well region 340.

The heavily doped portion 342 (source region) includes a heavily doped portion 3421 adjacent to the gate structure 3461 and a heavily doped portion 3422 adjacent to the gate structure 3462. The heavily doped portions 3421 and 3422 are in the P-type well region 340.

The heavily doped portion 344 (drain region) includes a heavily doped portion 3441 adjacent to the gate structure 3461 and a heavily doped portion 3442 adjacent to the gate structure 3462. The heavily doped portions 3441 and 3442 are in the two N-type well regions 341 respectively.

The heavily doped portion 345 (base region) is in the P-type well region 340 and is disposed between the two heavily doped portions 3421 and 3422 (source region).

Furthermore, according to some examples, a P-body region 340B is also formed in the P-type well region 340. The heavily doped portion 345 (base region) and the heavily doped portions 3421 and 3422 (source regions) are formed in the P-type body region 340B.

Furthermore, according to some examples, the doping concentration of the P-type well region 340 is smaller than the doping concentration of the heavily doped portion 342 (including 3421 and 3422; source region) and the heavily doped portion 344 (including 3441 and 3442; drain region). The doping concentration of the P-type body region 340B is smaller than the doping concentrations of the heavily doped portion 342 and the heavily doped portion 344.

Furthermore, in this example, a portion of the epitaxial layer 120, such as a portion of the second epitaxial material layer 112, is also included between the N-type well region 341 and the P-type well region 340 and the underlying isolation layer 104 to achieve better electrical isolation between the formed N-type LDMOS element (the fourth element 14) and the substrate 100 (e.g., n-type), thereby reducing the possible impact of the substrate 100 on the fourth element 14 during the operation of first element 11.

After the elements as illustrated in FIG. 5 are formed, an insulating layer (not shown) may be formed over the epitaxial layer 120, and the insulating layer covers the gate structures 16, 326, 336, and 346. Furthermore, a plurality of contacts (not shown) are formed in the insulating layer, these contacts connect the gate structure (16/326/336/346), drain region (324/334/344), and source region (322/332) of each element (11/12/13/14)/342) and base region (325/335/345).

In summary, according to the semiconductor structures and methods of manufacturing the same proposed in some embodiments of the present disclosure, the configuration of its isolation structure (e.g., including localized isolation layers and deep trench isolation elements) enables the integration of multiple different types of semiconductor elements on the same substrate (such as a wafer), especially semiconductor elements with different current directions. In the embodiment application, vertical semiconductor elements with vertical current direction, such as VDMOS elements, and non-vertical semiconductor elements with non-vertical current direction (such as horizontal direction), such as N/PMOS and LDMOS, may be integrated. According to some embodiments, a partially extending isolation layer is provided over the substrate, and one or more isolation regions may be defined by connecting the deep trench isolation to the isolation layer. The non-vertical semiconductor elements are disposed in the isolation region, and the vertical semiconductor elements are disposed in regions without isolation layers (i.e., outside the isolation regions). According to some embodiments, the substrate of the semiconductor structure includes a high doping concentration being used as a drain region of the vertical semiconductor element. Through the arrangement of the localized isolation layer, the impact of the substrate on the electrical performance of the non-vertical semiconductor element may be reduced, so that both the integrated vertical and non-vertical semiconductor elements may achieve excellent electrical performance. Therefore, according to the application of the embodiments of the present disclosure, BCD (including Bipolar elements, CMOS elements, and DMOS elements) and VDMOS elements may be integrated on the same wafer, which can comprehensively address complex application design problems with high-power requirements.

In addition, according to the manufacturing method proposed in some embodiments of the present disclosure, a locally extended isolation layer over a substrate and integrating semiconductor elements including different types of semiconductor elements may be acquired through a simple process compatible with existing manufacturing processes. When integrating different semiconductor elements, similar elements may be manufactured together in the same process, which reduces the number of required manufacturing steps. For example, multiple deep trench isolations may be formed in the same process, and well regions or heavily doped portions of the same conductivity type may be formed in the same process. Therefore, the manufacturing process of the embodiment is simple and does not significantly increase additional manufacturing costs.

Although the embodiments and their advantages of the present disclosure are disclosed above, it should be understood that anyone with ordinary skill in the art may make changes, substitutions, and modifications without departing from the spirit and scope of the present disclosure. In addition, the claimed scope of the present disclosure is not limited to the processes, machines, manufacturing, material compositions, elements, methods, and steps in the specific embodiments disclosed in the specification. Anyone with ordinary skill in the art may understand the processes, machines, manufacturing, material compositions, elements, methods, and steps currently or developed in the future from some embodiments of the present disclosure. As long as substantially the same functions may be implemented or substantially the same results may be obtained from the embodiments of the disclosure, they are all within the scope of the present disclosure. Therefore, the claimed scope of the present disclosure includes the above-mentioned processes, machines, manufacturing, material compositions, elements, methods, and steps. In addition, each claimed scope constitutes an individual embodiment, and the scope of the present disclosure also includes the combination of each claimed scope and embodiments.

What is claimed is:

1. A semiconductor structure, comprising:
a substrate;
an isolation layer over the substrate, wherein the isolation layer is in a second region of the semiconductor structure, but does not extend into a first region of the semiconductor structure;
an epitaxial layer over the substrate and covering the isolation layer;
a deep trench isolation extending downward into the epitaxial layer and connecting the isolation layer;
a first element in the first region, wherein the substrate serves as a drain region of the first element; and
a second element in the second region, wherein the second element is in an isolation region defined by the deep trench isolation and the isolation layer.

2. The semiconductor structure as claimed in claim 1, wherein a lower portion of the deep trench isolation extends from a top surface of the isolation layer to a bottom surface of the isolation layer.

3. The semiconductor structure as claimed in claim 1, wherein the isolation layer contacts a top surface of the substrate.

4. The semiconductor structure as claimed in claim 3, wherein a bottom surface of the deep trench isolation contacts the top surface of the substrate.

5. The semiconductor structure as claimed in claim 1, wherein the epitaxial layer further comprises:
a first epitaxial material layer on the substrate and extending into the first region and the second region of the semiconductor structure, wherein the isolation layer is on the first epitaxial material layer; and
a second epitaxial material layer on the first epitaxial material layer and covering the isolation layer,
wherein, the deep trench isolation extends downward into the second epitaxial material layer and is connected to the isolation layer.

6. The semiconductor structure as claimed in claim 5, wherein the isolation layer is formed directly on a top surface of the first epitaxial material layer.

7. The semiconductor structure as claimed in claim 5, wherein a bottom surface of the deep trench isolation contacts a top surface of the first epitaxial material layer.

8. The semiconductor structure as claimed in claim 1, wherein the deep trench isolation passes through the isolation layer, and wherein a bottom surface of the deep trench isolation is coplanar with a bottom surface of the isolation layer.

9. The semiconductor structure as claimed in claim 1, wherein a driving current of the first element flows from a top surface of the epitaxial layer toward the substrate, and wherein a driving current of the second element flows along the top surface of the epitaxial layer.

10. The semiconductor structure as claimed in claim 1, wherein the substrate and the epitaxial layer have a same conductivity type, and wherein a doping concentration of the substrate is greater than a doping concentration of the epitaxial layer.

11. The semiconductor structure as claimed in claim 1, wherein the isolation layer extends continuously from the second region to a third region of the semiconductor structure, and wherein the second region is between the third region and the first region.

12. The semiconductor structure as claimed in claim 11, further comprising:
a third element in the third region,
wherein a current direction of the third element flows along a direction of a top surface of the epitaxial layer.

13. The semiconductor structure as claimed in claim 12, wherein the deep trench isolation is a first deep trench isolation disposed in the second region, and wherein the second element is in an isolation region defined by the first deep trench isolation and the isolation layer, and wherein the semiconductor structure further comprises:
a second deep trench isolation disposed in the third region, wherein the second deep trench isolation and the first deep trench isolation are laterally separated by a distance,
wherein the third element is in another isolation region defined by the second deep trench isolation and the isolation layer.

14. A method of manufacturing a semiconductor structure, comprising:
forming an isolation layer over a substrate, wherein the isolation layer is in a second region of the semiconductor structure but does not extend into a first region of the semiconductor structure;
forming an epitaxial layer over the substrate and covering the isolation layer;
forming a deep trench isolation extending downward into the epitaxial layer, wherein the deep trench isolation connects the isolation layer;
forming a first element in the first region, wherein the substrate serves as a drain region of the first element; and
forming a second element in the second region, wherein the second element is in an isolation region defined by the deep trench isolation and the isolation layer.

15. The method of manufacturing a semiconductor structure as claimed in claim 14, wherein forming the isolation layer over the substrate comprises:
providing the substrate;
forming a silicon-containing oxide layer over a top surface of the substrate;
bonding the silicon-containing oxide layer with a base material, wherein after the bonding, the silicon-containing oxide layer is between the base material and the substrate;
removing a portion of the base material, wherein a remaining portion of the base material is a donor layer on the silicon-containing oxide layer;
forming a mask over the donor layer;
removing a portion of the donor layer and a portion of the silicon-containing oxide layer according to the mask, wherein a remaining portion of the donor layer forms a donor portion, and wherein a remaining portion of the silicon-containing oxide layer forms the isolation layer; and
removing the mask.

16. The method of manufacturing a semiconductor structure as claimed in claim 15, wherein the base material has a weakened layer, and after the silicon-containing oxide layer is bonded with the base material, there is a vertical spacing between the weakened layer and the silicon-containing oxide layer, and the method further comprises:
performing a peeling step from the weakened layer to remove the portion of the base material, wherein a remaining portion of the base material is the donor layer, and the donor layer remains on the silicon-containing oxide layer.

17. The method of manufacturing a semiconductor structure as claimed in claim 15, wherein after the silicon-containing oxide layer is bonded with the base material, the method further comprises:
performing a thinning process on the base material to remove the portion of the base material.

18. The method of manufacturing a semiconductor structure as claimed in claim 15, wherein after providing the substrate, a thermal oxidation process is performed on the substrate to form the silicon-containing oxide layer on the top surface of the substrate.

19. The method of manufacturing a semiconductor structure as claimed in claim 15, wherein the epitaxial layer is excessively formed on the substrate, and wherein the epitaxial layer covers a top surface and side surfaces of the donor portion, and covers side surfaces of the isolation layer.

20. The method of manufacturing a semiconductor structure as claimed in claim 19, wherein the deep trench isolation thus formed extends downward from a top surface of the epitaxial layer to a bottom surface and connects the isolation layer,
wherein an inner sidewall of the deep trench isolation contacts an excess portion of the epitaxial layer, the donor portion and the isolation layer in sequence from top to bottom.

21. The method of manufacturing a semiconductor structure as claimed in claim 14, wherein the epitaxial layer further comprises:
a first epitaxial material layer on the substrate and extending into the first region and the second region of the semiconductor structures, wherein the isolation layer is over the first epitaxial material layer; and
a second epitaxial material layer on the first epitaxial material layer and covering the isolation layer, wherein the deep trench isolation extends downward into the second epitaxial material layer and is connected to the isolation layer.

22. The method of manufacturing a semiconductor structure as claimed in claim 21, wherein the isolation layer is formed directly on a top surface of the first epitaxial material layer.

23. The method of manufacturing a semiconductor structure as claimed in claim 22, wherein a bottom surface of the deep trench isolation thus formed contacts the top surface of the first epitaxial material layer.

24. The method of manufacturing a semiconductor structure as claimed in claim 14, wherein a driving current of the first element flows from a top surface of the epitaxial layer toward the substrate, and wherein a driving current of the second element flows along a direction of a top surface of the epitaxial layer.

25. The method of manufacturing a semiconductor structure as claimed in claim 14, wherein the isolation layer extends continuously from the second region to a third region of the semiconductor structure, and wherein the second region is between the third region and the first region.
